(19) United States
(12) Patent Application Publication
(10) Pub. No.: US 2026/0195500 A1
(43) Pub. Date: Jul. 9, 2026

(54) ASSESSING THE EFFICACY OF TEST MEASUREMENTS IN PARAMETER CHARACTERIZATION OF GEOLOGICAL MODELS

(71) Applicant: Schlumberger Technology Corporation, Sugar Land, TX (US)

(72) Inventors: Lei Jiang, Cambridge, MA (US); Florian Hollaender, Cambridge, MA (US); Morten Kristensen, Lysaker (NO); William J. Bailey, Cambridge, MA (US)

(21) Appl. No.: 19/442,138

(22) Filed: Jan. 7, 2026

Related U.S. Application Data
(60) Provisional application No. 63/742,617, filed on Jan. 7, 2025.

(51) Int. Cl. G06F 30/20; G01V 1/28

(52) U.S. Cl. CPC G06F 30/20; G01V 1/282; G01V 2210/6652; G01V 2210/667

(57) ABSTRACT

A method may include identifying known parameters based on a geological model representative of a subsurface region and identifying uncertain parameters associated with the geological model based on the known parameters and field operations previously performed within the subsurface region. The operations may also include generating a simulated test design to estimate the uncertain parameters based on the known parameters by determining a sensitivity coefficient matrix at different time points for each of one or more simulated measurements associated with estimated uncertain parameters based on the simulated test design and determining a residual uncertainty associated with the estimated uncertain parameters based on the sensitivity coefficient matrix. The method may also include generating an updated simulated test design to estimate the second set of parameters based on the known parameters in response to the residual uncertainty being greater than a threshold.

### CROSS-REFERENCE TO RELATED APPLICATION

This application claims priority to and the benefit of U.S. Provisional Application Ser. No. 63/742,617, entitled “A METHODOLOGY FOR ASSESSING THE EFFICACY OF TEST MEASUREMENTS IN PARAMETER CHARACTERIZATION” and filed Jan. 7, 2025, the disclosure of which is incorporated herein by reference in its entirety for all purposes.

### BACKGROUND

The present disclosure is generally related to generating accurate geological models for geological reservoir development applied to the production and/or injection of fluids. More specifically, the present disclosure is generally related to generating accurate geological models by assessing uncertain parameters through adequate acquisition program design using already-known parameters for activities linked to the geological reservoir (e.g. improved drilling, operational planning, resource evaluation, facilities design). Wells are generally drilled into the ground or ocean bed to recover natural deposits of hydrocarbon deposits, such as oil, gas, and other materials that may be trapped in subterranean formations. Alternatively, wells be may drilled to access thermal resources such as for geothermal power generation, or may be used to connect to storage complexes, temporary for natural gas or hydrogen, or permanent for carbon dioxide capture and storage. Well construction operations (e.g., drilling operations) may be performed at a wellsite by a well construction system (e.g., drilling rig) having various surface and subterranean well construction equipment being operated in a coordinated manner.

Operators may monitor and analyze a wide breadth of information to optimize efficiency and safety, supporting applications that encompass the full spectrum from well construction and reservoir characterization through to production and/or injection operation. In some cases, measurements acquired from the borehole or well may be processed to analyze various characteristics of a subterranean region. However, some measurements related to certain parameters used to characterize a subterranean region may not be available making it difficult to assess the planned operation of the geological reservoir or make adjustment to the drilling, production and/or injection operations being performed during the lifetime of the project.

This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, it should be understood that these statements are to be read in this light, and not as admission of prior art.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In some embodiments, a system may include a processing system comprising one or more processors, a memory storing instructions, that when executed by the processing system, are configured to cause the processing system to perform operations including identifying a first set of parameters based on a geological model representative of a subsurface region and identifying a second set of parameters associated with the geological model based on the first set of parameters and one or more field operations previously performed within the subsurface region, wherein the second set of parameters is associated with one or more uncertain parameters. The operations may also include generating a simulated test design configured to estimate the second set of parameters based on the first set of parameters wherein generating a simulated test design includes determining a sensitivity coefficient matrix at one or more different time points for each of one or more simulated measurements associated with an estimated second set of parameters based on the simulated test design and determining a residual uncertainty associated with the estimated second set of parameters based on the sensitivity coefficient matrix. The operations may also include generating an updated simulated test design configured to estimate the second set of parameters based on the first set of parameters in response to the residual uncertainty being greater than a threshold.

In some embodiments, a tangible, non-transitory, computer-readable medium with instructions that, when executed by processing circuitry, may cause the processing system circuitry to perform operations including identifying a first set of parameters based on a geological model representative of a subsurface region and identifying a second set of parameters associated with the geological model based on the first set of parameters and one or more field operations previously performed within the subsurface region, wherein the second set of parameters is associated with one or more uncertain parameters. The operations may also include generating a simulated test design configured to estimate the second set of parameters based on the first set of parameters wherein generating a simulated test design includes determining a sensitivity coefficient matrix at one or more different time points for each of one or more simulated measurements associated with the estimated second set of parameters based on the simulated test design and determining a residual uncertainty associated with the estimated second set of parameters based on the sensitivity coefficient matrix. The operations may also include generating an updated simulated test design configured to estimate the second set of parameters based on the first set of parameters in response to the residual uncertainty being greater than a threshold.

In some embodiments, a method includes identifying a first set of parameters based on a geological model representative of a subsurface region and identifying a second set of parameters associated with the geological model based on the first set of parameters and one or more field operations previously performed within the subsurface region, wherein the second set of parameters is associated with one or more uncertain parameters. The method may also include generating a simulated test design configured to estimate the second set of parameters based on the first set of parameters wherein generating a simulated test design includes determining a sensitivity coefficient matrix at one or more different time points for each of one or more simulated measurements associated with the estimated second set of parameters based on the simulated test design and determining a residual uncertainty associated with the estimated second set of parameters based on the sensitivity coefficient matrix. The method may also include generating an updated simulated test design configured to estimate the second set of parameters based on the first set of parameters in response to the residual uncertainty being greater than a threshold.

The brief summary presented above is intended only to familiarize the reader with certain aspects and contexts of embodiments of the present disclosure without limitation to the claimed subject matter.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIG. 1 illustrates an example drilling system that may employ the systems and methods of this disclosure, in accordance with embodiments of the present disclosure;

FIG. 2 is a flowchart of a method for generating a test design to account for uncertain parameters used to generate a geological model, in accordance with embodiments of the present disclosure;

FIG. 3 illustrates the residual uncertainty corresponding to 95% confidence interval for the prior maximum, mean, and minimum true values of the parameter, computed for a test design option with the method described in FIG. 2, in accordance with embodiments of the present disclosure;

FIG. 4 illustrates a smaller residual uncertainty corresponding to 95% confidence interval for the prior maximum, mean, and minimum true values of the parameter for an additional test design option as compared to the example test design option of FIG. 3, in accordance with embodiments of the present disclosure, and

FIG. 5 illustrates a smaller residual uncertainty corresponding to 95% confidence interval for the prior maximum, mean, and minimum true values of the parameter for a third test design option compared to test design options of FIG. 3 and FIG. 4, in accordance with embodiments of the present disclosure.

### DETAILED DESCRIPTION

Certain embodiments commensurate in scope with the present disclosure are summarized below. These embodiments are not intended to limit the scope of the disclosure, but rather these embodiments are intended only to provide a brief summary of certain disclosed embodiments. Indeed, the present disclosure may encompass a variety of forms that may be similar to or different from the embodiments set forth below.

As used herein, the term “coupled” or “coupled to” may indicate establishing either a direct or indirect connection (e.g., where the connection may not include or include intermediate or intervening components between those coupled), and is not limited to either unless expressly referenced as such. The term “set” may refer to one or more items. Wherever possible, like or identical reference numerals are used in the figures to identify common or the same elements. The figures are not necessarily to scale and certain features and certain views of the figures may be shown exaggerated in scale for purposes of clarification.

As used herein, the terms “inner” and “outer”; “up” and “down”; “upper” and “lower”; “upward” and “downward”; “above” and “below”; “inward” and “outward”; and other like terms as used herein refer to relative positions to one another and are not intended to denote a particular direction or spatial orientation. The terms “couple,” “coupled,” “connect,” “connection,” “connected,” “in connection with,” and “connecting” refer to “in direct connection with” or “in connection with via one or more intermediate elements or members.”

Furthermore, when introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment,” “an embodiment,” or “some embodiments” of the present disclosure are not intended to be interpreted as excluding the existence of additional embodiments that also incorporate the recited features. Furthermore, the phrase A “based on” B is intended to mean that A is at least partially based on B. Moreover, unless expressly stated otherwise, the term “or” is intended to be inclusive (e.g., logical OR) and not exclusive (e.g., logical XOR). In other words, the phrase A “or” B is intended to mean A, B, or both A and B.

Geological reservoir development operations rely on accurate characterization of parameters related to various properties of the geologic region in which a fluids reservoir may be positioned. As such, in order to generate plans related to developing (e.g., exploring, producing, injecting into) geological reservoirs, geological models related to the respective subsurface regions of the Earth may be used to plan for certain geological reservoir development operations (e.g., drilling, producing or storing). To generate accurate geological models, various parameters (e.g., reservoir boundaries, permeability, anisotropy, reservoir pressure) regarding the corresponding subsurface regions of the geological region may be used to characterize properties of the respective subsurface regions of the Earth and build the respective geological model. However, certain parameter data useful for building these geological models may not be directly measurable or available due to limitations in tools, sensors, or other equipment, or to other techno-economical choices.

With the foregoing in mind, the unavailable parameter data may be initially inferred using the available parameter data. However, the accuracy or confidence level of the inferred parameter data may range based on the processes employed to generate the inferred parameter data and on the uncertainty in associated measurements. To better characterize the unavailable parameters, many different test design options (e.g., different tools or operation plans) are available. However, it may be challenging to evaluate different test designs with respect to their effectiveness for characterizing the unavailable parameters. To address that, the present embodiments described herein may include a computing system that may infer the unknown parameter data (e.g. data that remains to be evaluated) and their residual uncertainty based on the simulated measurements from potential test designs. To do that, the proposed methodology introduces surrogate models that characterize relationships between the simulated measurements by test designs and the unknown parameter data.

In some embodiments, these relationships may be characterized according to some function (e.g., ƒ(m, t), where m corresponds to unknown parameters and t corresponds to time), and the surrogate model may be generated based on simulated measurements extracted from various simulations related to test designs performed on the geological region incorporating estimated uncertainties. As such, the computing system may identify the optimal test designs that most effectively characterize the uncertain parameters (e.g. data that remains to be evaluated) by analyzing the expected behavior of the simulated measurements from different test designs according to the respective functions. The computing system may iteratively compute a sensitivity coefficient matrix at various times to quantify the influence of simulated measurements on the reduction of residual uncertainty of the unknown parameters. In some embodiments, the computing system may continuously adjust the test design until the confidence interval of the uncertain parameters meets some predefined thresholds. By leveraging the surrogate models, the computing system significantly reduces the number of numerical simulations that may be executed by other computing systems and other methodologies to obtain the same uncertain parameters at the same threshold confidence level. In this way, the present embodiments offer a more efficient and objective approach to identify the optimal test design for determining the residual uncertainty for unknown parameter data that may be used to generate or update a geological model.

Indeed, the present embodiments described herein provide objective evaluations of the efficacy of different test designs, determine optimal test designs and durations for parameter characterization (e.g. which may include selecting the optimal measurement tool from various petrophysical logs, optimizing the best time to perform a measurement, optimizing the preferred sequence of injection and/or production for sequential data acquisition, etc.), and quantify parameter uncertainty levels following the interpretation of the test data. Moreover, the present embodiments allow for informed decisions to be made about test designs to meet specific objectives, thereby providing a robust framework for evaluating test designs across various applications, including reservoir development, CO2 injectivity, storage de-risking, and the like. As a result, the systems and methods described herein support efficient and accurate geological modeling using fewer computational resources (e.g., time, energy).

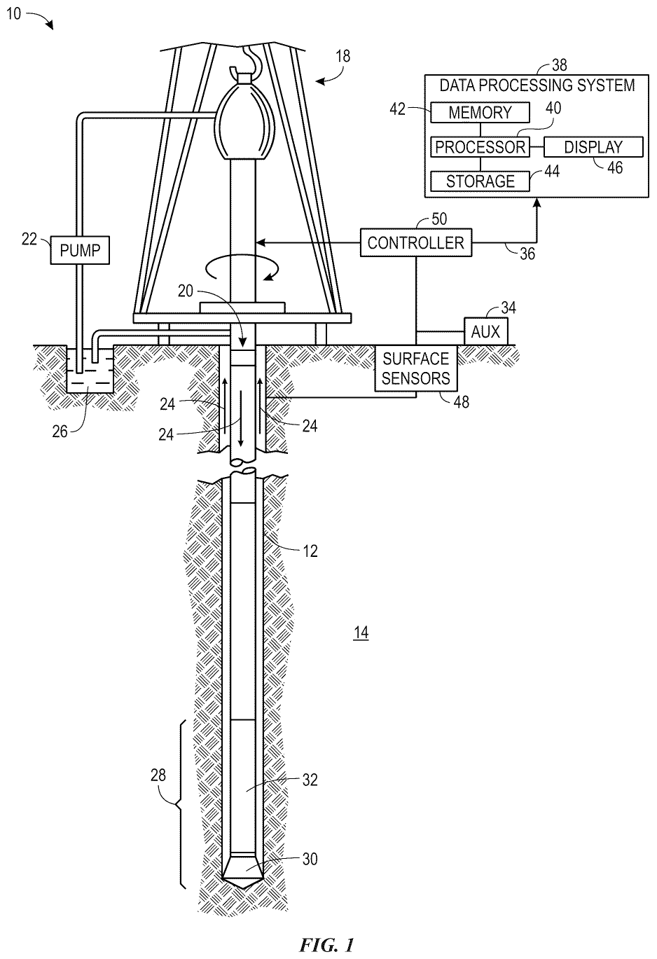

By way of introduction, FIG. 1 illustrates a drilling system 10 that may employ the systems and methods of this disclosure. The drilling system 10 may be used to drill a borehole 12 into a geological region 14. In the drilling system 10, a drilling rig 18 may rotate a drill string 20 within the borehole 12. As the drill string 20 is rotated, a drilling fluid pump 22 may be used to pump drilling fluid, which may be referred to as “mud” or “drilling mud,” downward through the center of the drill string 20, and back up around the drill string 20, as shown by reference arrows 24. At the surface, return drilling fluid may be filtered and conveyed back to a mud pit 26 for reuse. The drilling fluid may travel down to the bottom of the drill string 20 known as the bottom-hole assembly (BHA) 28. The drilling fluid may be used to rotate, cool, and/or lubricate a drill bit 30 that may be a part of the BHA 28. The fluid may exit the drill string 20 through the drill bit 30 and carry drill cuttings away from the bottom of the borehole 12 back to the surface. One or more sensors 48 may record a variety of different data points associated with the drilling system 10, including the rotations per minute (RPM) of the drill string 20 and/or the drill bit 30. For example, the set of sensors 48 may determine the surface RPM of the drilling system 10. In addition, the sensors 48 may be positioned within the drill string 20 to capture data related to properties of the drill string 20, the drill bit 30, and the like while inside the borehole 12.

The BHA 28 may include the drill bit 30 along with various downhole tools, such as one or more logging tools 32. The BHA 28 may thus convey the one or more logging tools 32 through the geological region 14 via the borehole 12. As described in greater detail herein, the one or more logging tools 32 may be any suitable downhole tool that emits various signals within the borehole 12 (e.g., a downhole environment) such as electromagnetic, acoustic, nuclear or other. The downhole tools, which may include the one or more logging tools 32, may collect a variety of information relating to the geological region 14 and the state of drilling in the borehole 12. For instance, the downhole tools may be logging-while drilling (LWD) tools that measure physical properties of the geological region 14, such as density, porosity, resistivity, lithology, and so forth. Likewise, the downhole tools may be measurement-while-drilling (MWD) tools that measure certain drilling parameters, such as the temperature, pressure, orientation of the drill bit 30, mapping-while-drilling tools, and so forth. Alternatively, such measurements may be acquired using wireline logging tools, coil tubing or drillstem testing-carried equipment, or may be left permanently in the wellbore by means of instrumented completions, In yet another embodiment, tools may be used to capture fluid or rocks samples to be analyzed in facilities at or away from the wellsite. In certain embodiments, measurements acquired from LWD tools may be used to generate a geological model that may represent the subsurface of the geological region. However, certain parameters (e.g. horizontal permeability, anisotropy, and fault distance) that may be used to generate the geological models to characterize the geological region may not be available. The geological model may be utilized to adjust drilling variables (e.g., speed, weight-on-bit, RPM, fluid properties, torque, depth, azimuth, inclination) for drilling operations, or simulation models for operational planning and execution. In other embodiments, the present embodiments described herein may be implemented for evaluating test design in various domains such as petrophysical logging and CO2 injection de-risking.

The one or more logging tools 32 may receive energy from an electrical energy device or an electrical energy storage device, such as an auxiliary power source 34 or another electrical energy source to power the tool. In some embodiments, the one or more logging tools 32 may include a power source within the one or more logging tools 32, such as a battery system or a capacitor, to store sufficient electrical energy to emit and/or receive electromagnetic waves.

The drilling system 10 may include a controller 50 to control different components of the drilling system 10 and collect identified data from the one or more logging tools 32 and/or the one or more sensors 48. The controller 50 may be any electronic data processing system that can be used to carry out the systems and methods of this disclosure. That is, the controller 50 may monitor and regulate various operational parameters of the drilling system 10. The controller 50 may receive data from the sensors (e.g., the one or more sensors 48 and/or one or more logging tools 32) measuring parameters such as drilling depth, rotational speed, torque, pressure, and vibration. Based on these inputs, the controller 50 may perform various actions adjusting drilling variables, such as a bit rotation speed, a feed rate, a fluid flow, and the like.

Communications 36, such as control signals, may be transmitted from a data processing system 38 to the controller 50 and the communications 36, such as data signals related to the results/measurements of the sensors 48 and/or one or more logging tools 32, may be returned to the data processing system 38 via the controller 50. The data processing system 38 may be any electronic data processing system that can be used to carry out the systems and methods of this disclosure. For example, the data processing system 38 may include one or more processors 40, which may execute instructions stored in memory 42 and/or storage 44. The memory 42 and/or the storage 44 of the data processing system 38 may be any suitable article of manufacture that can store the instructions. In certain embodiments, the one or more processors 40 may include a microprocessor, a microcontroller, a processor module or subsystem, a programmable integrated circuit, a programmable gate array, a digital signal processor (DSP), or another control or computing device. In certain embodiments, the one or more processors 40 may include machine learning and/or artificial intelligence (AI) based processors. The machine learning processors may utilize the first set of parameters and the second set of parameters to create geological models in accordance with embodiments presented below to predict properties associated with the subsurface of the geological region being evaluated.

In certain embodiments, the memory 42 and storage 44 may be implemented as one or more non-transitory computer-readable or machine-readable storage media. In certain embodiments, the memory 42 may include one or more different forms of memory, including semiconductor memory devices such as dynamic or static random access memories (DRAMs or SRAMs), erasable and programmable read-only memories (EPROMs), electrically erasable and programmable read-only memories (EEPROMs) and flash memories. The storage 44 may include solid state drives, magnetic disks such as fixed, floppy and removable disks; other magnetic media including tape; optical media such as compact disks (CDs) or digital video disks (DVDs); or other types of storage devices. Note that the computer-executable instructions and associated data of the analysis module(s) may be provided on one computer-readable or machine-readable storage medium of the memory 42 or the storage 44, or alternatively, may be provided on multiple computer-readable or machine-readable storage media distributed in a large system having possibly plural nodes. Such computer-readable or machine-readable storage medium or media are considered to be part of an article (or article of manufacture), which may refer to any manufactured single component or multiple components. In certain embodiments, the storage 44 may be located either in the machine running the machine-readable instructions or may be located at a remote site from which machine-readable instructions may be downloaded over a network for execution.

As illustrated, the data processing system 38 may optionally also include a display 46, which may be any suitable electronic display, and may display the geological model generated by the processor 40. The data processing system 38 may be a local component of the drilling system 10 (i.e., at the surface), within the one or more logging tools 32 (i.e., downhole), a device located proximate to the drilling operation, and/or a remote data processing device located away from the drilling system 10 to process downhole measurements in real time or sometime after the data has been collected. In some embodiments, the data processing system 38 may be a portable computing device (e.g., tablet, smart phone, or laptop) or a server remote from the drilling system 10. In some embodiments, the one or more logging tools 32 may store and process collected data in the BHA 28 or send the data to the surface for processing via communications 36 described above, including any suitable telemetry (e.g., electrical signals pulsed through the geological region 14 or mud pulse telemetry using the drilling fluid).

In certain embodiments, a wireline system may employ the systems and methods of this disclosure. The wireline system may be used to convey a downhole tool string through a geological formation via a wellbore (e.g., completed wellbore) to perform various operations such as well logging, maintenance, interventions, perforation, and the like. In some embodiments, a casing may be disposed within the wellbore, such that the downhole tool string may traverse the wellbore within the casing. In some embodiments, a cement lining may be positioned between the casing and the geological formation, such that the casing is cemented (e.g., affixed to) the surrounding geological formation.

The downhole tool string may be conveyed through the wellbore via a cable of the wireline system. The wireline system may be substantially fixed (e.g., a long-term installation that is substantially permanent or modular) or may be a mobile wireline system, such as a wireline system carried by a truck. Any suitable cable may be used to convey the downhole tool string through the wellbore.

The wireline system may also include the data processing system 38 or other suitable control system that may control operations of the wireline system and/or the downhole tool string. Indeed, the data processing system may enable autonomous operation of the downhole tool string 12 within the wellbore. In some embodiments, the wireline system includes wellbore equipment or pressure control equipment disposed near a surface of the geological formation. The pressure control equipment enables the cable to move the downhole tool string through the wellbore, while substantially blocking pressurized fluid within the wellbore from leaking into an ambient environment (e.g., the atmosphere). In some embodiments, the pressure control equipment includes a pack-off that may form a fluidic seal around the cable. For example, the cable may pass through an annular opening within the pack-off that may conform to an external surface of the cable, thus forming the fluid seal. Accordingly, the pack-off may mitigate wellbore fluids or other contaminants, such as grease, from entering the wellbore or discharging from the wellbore 16. It should be appreciated that the pressure control equipment may include any other suitable components or combination of components that may facilitate traversing the cable 18 and the downhole tool string through the wellbore. That is, the pressure control equipment 33 may additionally include, for example, a lubricator, a tool trap, a pump-in-sub, a cable shearing device, multiple motorized rollers, or any other suitable component(s).

It should be noted that, although the discussion above relates to a drilling system and a wireline system, other downhole equipment or systems may employ the systems and methods of this disclosure. For example, a downhole tool with an acoustic tool conveyed by slickline, coiled tubing, or other delivery systems, may utilize the disclosed systems and methods.

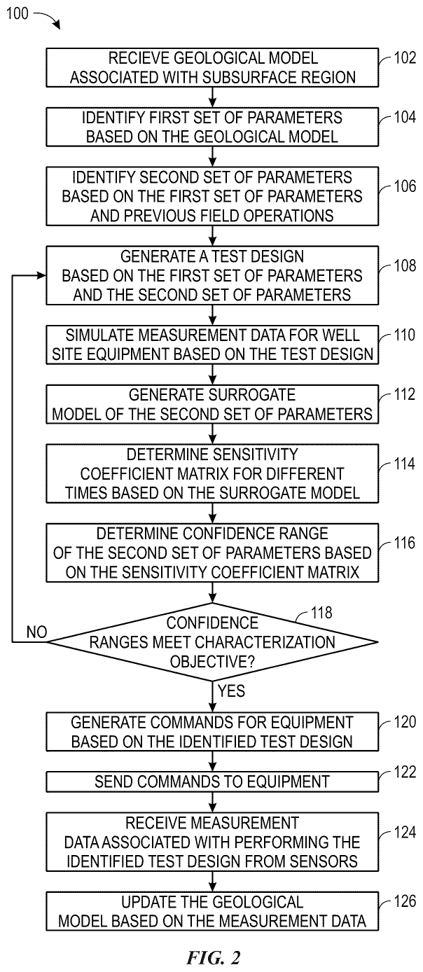

With the foregoing in mind, FIG. 2 illustrates a flowchart of a method 100 for employing a drilling system of FIG. 1 to adjust the drilling operation within a well based on a set of parameters associated with the well and a corresponding geological model. Although the following description of the method 100 is described as being performed by the data processing system 38, it should be noted that the method 100 may be performed by any suitable computing system and in any suitable order.

Referring now to FIG. 2, at block 102, the data processing system 38 may receive a geological model associated with the subsurface geological region. The geological model may include subterranean measurements and other representations of geological formations to provide information related to one or more properties (e.g., porosity, lithography, water saturation) associated with the subsurface geological region. The geological model may be stored in a storage component, such as a database that may store a number of geological models that may correspond to different subsurface geological regions of the world. By way of example, the geological model may provide information related to lithographical properties of the subsurface geological region to assist drilling systems to identify certain rock layers, detect hydrocarbon deposits, determine angle and azimuth for drilling wells, and the like. In some embodiments, the geological model may be generated based on measurements acquired by LWD or other suitable tools that may measure physical properties of the geological region, such as density, porosity, resistivity, lithology and so forth. As such, the geological model may help guide the drilling system efficiently (e.g., less energy, time) drill into the geological region.

In some embodiments, the geological model may be generated based on data acquired from the LWD tools, such as resistivity data and the like. For instance, electromagnetic fields may be output into the geological regions and the LWD tools may detect resistivity data related to properties of the geologic region, such as resistivity of formations, composition of the formations, presence of fluids within the reservoirs, and the like. The resistivity properties may be used to build the geological model of the geologic region that may be used to guide the drilling of the wellbore in a direction based on the locations of fluids within a hydrocarbon deposit or the like.

As mentioned above, to generate accurate geological models, various parameters (e.g., reservoir boundaries, permeability, anisotropy, reservoir pressure) regarding the corresponding subsurface regions of the geological region may be used to characterize properties of the respective subsurface regions of the Earth and build the respective geological model. However, certain parameter data for building these geological models may not be directly measurable or available due to limitations in tools, sensors, or other equipment, or to other techno-economical choices.

As such, some parameter data that may be useful in generating an accurate geological model may not be measured or available for use. With this in mind, to better characterize the unavailable parameters, many different test design options (e.g., different tools or operation plans) are available. To identify a suitable test design option for determining the unavailable parameters, the data processing system 38 may infer the unknown parameter data and their residual uncertainty based on the simulated measurements from potential test designs by employing a machine learning model (e.g. surrogate model) that characterizes relationships between the potential simulated measurements by the potential test designs, which may use the known parameters (e.g., first set of parameters), and the unknown parameter data (e.g. a second set of parameters). The resulting unknown parameter data may eventually be used to determine an accurate geological model for the corresponding subsurface geologic region.

With this in mind, at block 104, the data processing system 38 may identify the first set of parameters or known parameters that may be defined within the geological model received at block 102. The first set of parameters may include parameter data measured using tools, sensors, or other equipment and a-priori information. The first set of parameters may also be designated as known data based on metadata or other data characterizing features provided within the geological model. Further, the first set of parameters may also be associated with known parameters that remain static within the test design, such as certain properties associated with the corresponding geological region. That is, the first set of parameters may not be varied within the test design. In addition, the first set of parameters may be determined to be known data based on timestamps or measurement information that provides insight into the manner in which the data was acquired. That is, the first set of parameters may be inferred as being known data based on the data processing system 38 associating timestamps (e.g., historic data) to datasets acquired by sensors or other tools at various different times. In any case, the first set of parameters may provide insight into expected properties of the geological region that may be determined based on the geological model associated with the subsurface geological region received at block 102. For example, the first set of parameters may include porosity, formation thickness, viscosity, and the like.

At block 106, the data processing system 38 may identify a second set of parameters or unknown parameters that may be defined in the geological model based on the first set of parameters and/or identified in previous field operations (e.g., drilling, producing, storing). For instance, the geological model may characterize or tag datasets (e.g. horizontal permeability, permeability anisotropy, and fault distance) within the model or used by the model as unknown or uncertain datasets. The second set of parameters may be associated with some amount of uncertainty because they may not have been directly measured by sensors, tools, or the like. Instead, the second set of parameters may be estimated or simulated using known datasets, such as the first set of parameters. As such, the second set of parameters is associated with one or more uncertain or unknown parameters that remain to be evaluated by the test design. In some embodiments the second set of parameters may be manually inputted into the data processing system 38 by the user, determined based on functions or equations related to the first set of parameters, estimated based on simulations, estimated based on historical data, or the like. Since the second set of parameters are estimated or manually input, the parameters of the second set of parameters may have some uncertainty or may be related to some uncertainty range. The uncertainty range may be determined based on the manner in which the corresponding parameters are determined. In addition, a user may provide some uncertainty value for the corresponding parameter. In any case, the second set of parameters may provide insight into certain properties of the geological region that may not be captured by the first set of parameter data, measured using some equipment, or the like. However, as will be discussed in more detail below, the second set of parameters may be determined based on a function or relationship with the first set of parameters.

To characterize the second set of parameters, many different test design options (e.g., different tools or operation plans) may be useful to identify relationships between the simulated measurements from potential test designs and the second set of parameters. As such, at block 108, the data processing system 38 may generate a potential test design based on the first set of parameters and the second set of parameters. The test design may, for example, characterize the second set of parameters by performing some test operations in a corresponding system (e.g., drilling system 10) and measuring the feedback data from the system. That is, the test design may perform some action within the system to create a response within the system that may be measured using sensors or the like. The varied actions and measured response may provide some insight into the second set of parameters. By way of example, the test design may include deploying a dual-packer formation tester module into a well and performing a test schedule of 10-hours drawdown with a 10 barrels per day (bbl/d) pumping rate, followed by a 30-hours buildup period. Throughout the test and during the subsequent buildup period, the pressure response may be measured by a pressure gauge at the inlet of the dual-packer and used to determine another parameter associated with the well such as a formation permeability. That is, the test performed using the dual-packer and the measured pressure response may be used to ascertain some value for an unknown parameter. In some embodiments, the data processing system 38 may identify test objectives for test design based on the expected behavior of the first set of parameters and assess an accuracy or confidence level for the second set of parameters based on whether the test design met the test objectives.

In some embodiments, a number of test designs associated with determining various unknown parameters based on measured known quantities may be stored in a database or the like. As such, the data processing system 38 may generate the test design by querying the database using the known parameters, the unknown parameters, information related to the subsurface geologic region, and the like. That is, the data processing system 38 may employ machine learning algorithms or an artificial intelligence component to identity initial test designs for a particular set of known and unknown parameters within a particular geological region. In this way, the data processing system 38 may rely on historical observations of unknown parameter behavior based on known parameter feedback and corresponding test designs.

In addition, in some embodiments, the user may provide an input that may define the first simulated test design based on knowledge of historical observations. That is, the user may initialize the first simulated test design based on the user's knowledge of previous optimized designs stored in a database of the data processing system 38.

At block 110, the data processing system 38 may simulate measurement data for the second set of parameters for the well site equipment based on a current test design. That is, the data processing system 38 may infer measurement data for the second set of parameter data and their respective residual uncertainty based on the measured responses from the current test design. The simulated measurement data for the second set of parameter data may be processed by the data processing system 38 to generate a surrogate model.

At block 112, the data processing system 38 may generate a surrogate model of the simulated measurement data for the second set of parameters at different time points. In some embodiments, the surrogate model may be built using machine learning methods, Kriging method, Polynomial Chaos Expansion method, and the like. The surrogate model may characterize relationships between the potential simulated measurements by test designs and the unknown parameter data according to some function (e.g., ƒ(m, t), where m corresponds to unknown parameters and t corresponds to time). The surrogate model may thus be generated based on data acquired from various simulations related to test designs performed on the geological region.

By way of example, the second set of parameters may be used together with the first set of parameters as input for the surrogate model. As such, the surrogate model may approximate the modeled measurements ƒ_{i,j}(m) for the specific parameters set of the second set of parameters. Further, the data processing system 38 generate a graph to display the relationship between the modeled measurements ƒ_{i,j}(m) for the specific parameters set of the second set of parameters over different time points. The data processing system 38 may use the graph at block 114 to generate a sensitivity matrix coefficient. As such, the data processing system 38 may identify the optimal test designs to influence the second set of parameters by analyzing the expected behavior of the simulated measurements from test designs according to the respective simulations.

As mentioned above, the surrogate model may be used to approximate a modeled measurement ƒ_{i,j}(m) for a specific parameter of the second set of parameters. As such, this approach may reduce the number of numerical simulations that may be performed to accurately identify the second set of parameters. That is, the surrogate model may use fewer simulations for determining a specific parameter of the second set of parameters to calculate the modeled measurement ƒ_{i,j}(m) as compared to other numerical simulators.

At block 114, the data processing system 38 may determine the sensitivity coefficient matrix Gⱼ for different times based on the surrogate model to quantify the influence of simulated measurements on the reduction of residual uncertainty of the second set of parameters (e.g. estimated second set of parameters). The sensitivity coefficient matrix may be defined as:

$${G}_{j} ( m ) = [ \begin{matrix}\frac{\partial {f}_{1 , j} ( m )}{\partial {m}_{1}} & \frac{\partial {f}_{1 , j} ( m )}{\partial {m}_{2}} & … & \frac{\partial {f}_{1 , j} ( m )}{\partial {m}_{M}} \\ \frac{\partial {f}_{2 , j} ( m )}{\partial {m}_{1}} & \frac{\partial {f}_{2 , j} ( m )}{\partial {m}_{2}} & … & \frac{\partial {f}_{2 , j} ( m )}{\partial {m}_{M}} \\ ⋮ & ⋮ & … & ⋮ \\ \frac{\partial {f}_{{N}_{tj} , j} ( m )}{\partial {m}_{1}} & \frac{\partial {f}_{{N}_{tj} , j} ( m )}{\partial {m}_{2}} & … & \frac{\partial {f}_{{N}_{tj} , j} ( m )}{\partial {m}_{M}}\end{matrix} ]$$

where ƒ_{i,j}(m)=ƒⱼ(m, tᵢ) is the modeled measurement for the observed dataset j at time tᵢ. Furthermore, the data processing system 38 may determine the partial derivative,

$$\frac{\partial {f}_{i , j} ( m )}{\partial {m}_{k}} ,$$

of the modeled measurement ƒ_{i,j}(m) to a specific parameter mₖ to compute the sensitivity coefficient matrix. As such, the processing system 38 may use the surrogate model to determine the sensitivity coefficient matrix Gⱼ. For example, the modeled measurement ƒ_{i,j}(m) derived from the surrogate model constructed by the Polynomial Chaos Expansion may define the modeled measurement as:

$${f}_{i , j} ( m ) = {f}_{j} ( m , {t}_{i} ) \approx {f}_{j , PCE} ( m , {t}_{i} )$$

The partial derivative of the modeled measurement may be calculated using centered difference methods as such:

$$\frac{\partial {f}_{i , j} ( m )}{\partial {m}_{k}} \approx \frac{\begin{matrix}{f}_{j , PCE} ( {m}_{1} , … {m}_{k} + \frac{1}{2} δ {m}_{k} , … {m}_{M} , {t}_{i} ) - \\ {f}_{j , PCE} ( {m}_{1} , … {m}_{k} - \frac{1}{2} δ {m}_{k} , … {m}_{M} , {t}_{i} )\end{matrix}}{δ {m}_{k}}$$

where the δmₖ is an incremental and could be defined based on different scenarios. In some embodiments, the partial derivatives may be calculated by forward, backward or centered difference methods. As such, the data processing system 38 may iteratively compute the sensitivity matrix at different time to quantify a reduction in the residual uncertainty of the second set of parameters.

At block 116, the data processing system 38 may determine a residual uncertainty and associated confidence range (e.g., 95% confidence interval) associated with an estimated second set of parameters based on the sensitivity coefficient matrix. Further, the data processing system 38 may determine the confidence range of the second set of parameters at different time points. That is, the confidence range of the second set of parameters at different time points (e.g. or depth for measurements performed against a depth measure) may be used to determine certain features such as test duration, proper characterization of the parameters, efficacy of different test design contributors (flow schedule, rate, tool location, etc), estimate the parameters residual uncertainty, and the like.

With this in mind, in some embodiments, the data processing system 38 may perform history matching with the measured data and the modeled data to estimate the confidence range value of the second set of parameters m at a fixed time point (e.g. or depth). In some embodiments, the assumption may be made that the modeled response behaves linearly near the minimum of the objective function. The approximate confidence range for k-th parameter is computed as:

$${\tilde{m}}_{k} - 2 \sqrt{{( {H}^{- 1} )}_{k k}} \leq {{m}^{︶}}_{k} \leq {\tilde{m}}_{k} + 2 \sqrt{{( {H}^{- 1} )}_{k k}}$$

where \tilde{m}ₖ is the k-th estimated parameter, m̆ₖ is a true parameter value. H is the approximate Hessian Matrix nearing the value m̆ₖ and can be written as:

$$H = {\sum }_{j = 1}^{{N}_{s}} {G}_{j}^{T} {C}_{D , j}^{- 1} {G}_{j}$$

where C_{D,j} is the covariance matrix for measurement errors for the measured dataset j. Within each measured dataset j, if the noise for all the time point tᵢ is assumed to be independent and identically distributed with a normal distribution:

$${ε}_{j} ∼ 𝒩 ( 0 , {σ}_{j}^{2} )$$

the Covariance matrix C_{D,j} may be written as:

$${C}_{D , j} = {σ}_{j}^{2} {I}_{{N}_{tj}}$$

where Nₜⱼ is the total time point number in the measured dataset j.

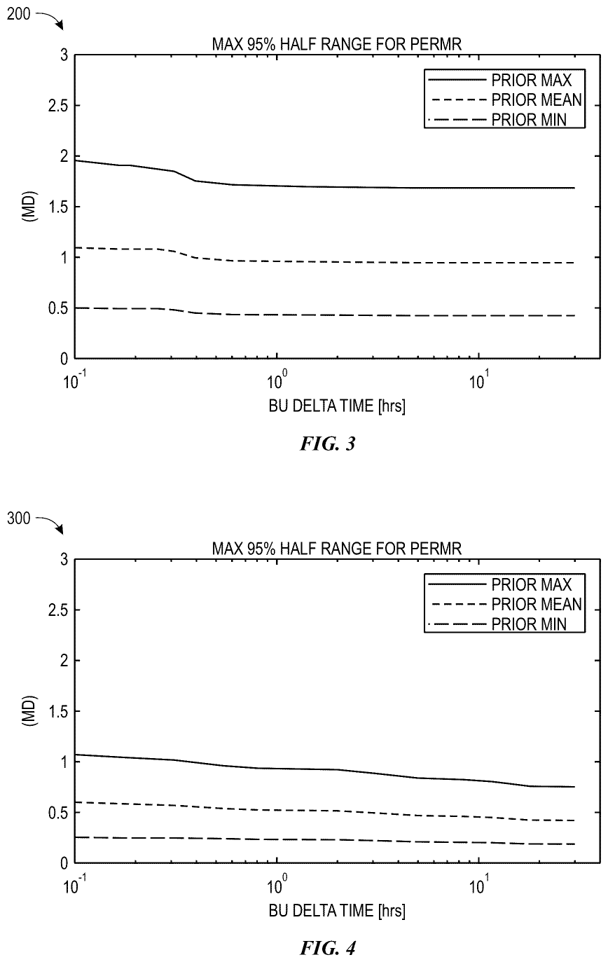

In some embodiments, the data processing system 38 may determine the confidence range of the second set of parameters at different time points. The data processing system 38 may perform this function by selecting different time (e.g. or depth) indices (Nₜⱼ=1, 2, 3, . . . ) when computing the sensitivity matrix coefficient. By way of reference, a subplot as shown with reference to FIG. 3, may be employed to determine the confidence range of the second set of parameters at different time points for a range of a true value of the parameter with respect to the prior uncertainty estimate.

At block 118, the data processing system 38 may determine if the residual uncertainty (e.g. posterior uncertainty) for each second set of parameters is within some characterization objective (e.g., achieving a parameter estimation uncertainty below a pre-defined threshold). For example, based on the determined residual uncertainties of the second set of parameters, the data processing system 38 may determine whether the current test design meets the test objectives. In response to the residual uncertainties of the second set of parameters being greater than the predefined threshold, the data processing system 38 may be configured to modify the candidate test design until test objectives are met. Further, in response to the current test design meeting the test objective, the data processing system 38 may proceed to block 120 and generate commands for drilling equipment. However, if the current test design does not meet the test objective, the data processing system 38 may generate an updated test design at block 108 to continue the method 100 until a test design meets the desired test objectives.

At block 120, the data processing system 38 may generate commands for controlling operations of equipment (e.g., drilling equipment, characterization equipment, production equipment, storage equipment) based on an identified test design or the current design that has the residual uncertainty for each second set of parameters within the characterization objective described above with respect to block 118. Using the identified test design that met the characterization objective at block 118, the data processing system 38 may generate commands for certain devices performing the identified test design within the subsurface geological region. That is, certain equipment (e.g., wireline tools) may be positioned within a borehole to perform operations defined by the identified test design. The commands may cause the equipment to initiate or adjust their respective operations in view of the test operations defined by the identified test design. For instance, the generated commands instructions may be related to adjusting a fluid pumping rate for producing fluid from or injecting fluid into the formation via a wireline conveyance tool.

At block 122, the data processing system 38 may send the commands to the equipment to cause the equipment to perform the corresponding operational adjustment. As such, the controller 50, for example, may receive the commands associated with the operational adjustments and adjust the operations of the equipment accordingly. The controller 50 may perform various actions to adjust variables associated with performing the identified test design, such as adjusting bit rotation speed, feed rate, fluid flow, and the like. In some embodiments, the controller 50 may operate as the data processing system 38 performing the method 100 or portions thereof.

At block 124, the data processing system 38 may receive measurement data associated with performing the identified test design from the sensors 48. That is, the data processing system 38 may receive actual sensor measurement data (e.g. data associated with performing the identified test design) that corresponds to the first set or known set of parameters and the second set or unknown set of parameters. That is, the identified test design may include operations that include performing some action (e.g., injecting fluid) and detecting a response (e.g., measurement data) that corresponds to the action. The response may be measured using sensors, calculated based on operational data associated with the equipment, or the like.

At block 126, the data processing system 38 may generate an updated geological model based on the measurement data received at block 124 to more accurately characterize various properties of the subsurface geological region. In some embodiments, before updating the geological model, the data processing system 38 may process or interpret the measurement data to estimate the true values of the second set of parameters (e.g., unknown parameters). That is, the data processing system 38 may estimate the actual values of the second set of parameters in geological structure. As such, the true values of the second set of parameters correspond to the real properties of the geological formation. The second set of parameters may be calculated based on certain relationships between the measurement data and the second set of parameters. That is, the measured responses to actions performed by the equipment may provide insight to estimate the expected or true values of the second set of parameters using real data, as opposed to the simulated data provided by the surrogate model. Using the measurement data and the calculated second set of parameters data (e.g. true value), the data processing system 38 may update the geological model to obtain a more accurate view of properties that may be part of the subsurface region associated with the operations being performed (e.g., drilling, characterization, producing, storing) therein.

In some embodiments, the data processing system 38 may then generate commands for devices performing certain operations (e.g., drilling, characterization, producing, storing) within the subsurface geological region based on the updated geological model. That is, the data processing system 38 may use the updated geological model to adjust the respective operations of the devices associated with a well, a borehole, or subsurface geological region in view of the expected properties of the subsurface geological region represented by the updated geological model. For instance, the generated commands instructions may be related to adjusting the speed of a motor of drill equipment at certain depths of the borehole in view of the updated geological model indicating that certain properties (e.g., lithology) of the borehole are changing.

The data processing system 38 may then send the commands to the equipment to cause the equipment to perform the corresponding operational adjustment. For example, the controller 50 may receive the commands associated with the drilling operation adjustments and adjust a drilling rig 18 accordingly. The controller 50 may perform various actions to adjust drilling variables, such as bit rotation speed, feed rate, fluid flow, and the like in real time.

Referring back to block 118, in response to the current test design not meeting the test objective, the data processing system 38 may return to block 108 and generate a different or updated test design based on the first set of parameters, the second set of parameters, and the simulated measurements from the previously simulated test design. That is, the different test design may be generated based on the previous simulated measurements or outputs provided by the previously generated test design. The different test design may use the simulated measurements of the previous test design to improve the residual uncertainty of the second set of parameters using adjustments to processes performed by the respective test design. This process may continue until the residual uncertainty and associated confidence range reaches the characterization objective. As such, the data processing system 38 may iteratively perform blocks 108-118 to continuously adjust the test design until the residual uncertainty and associated confidence range of the uncertain parameters meets some predefined thresholds or characterization objectives.

With this in mind, in response to the simulating test design meeting the predefined thresholds or characterization objectives, the data processing system 38 may be configured to estimate the second set of parameters based on the first set of parameters. That is, in response to the residual uncertainty being greater than the user-defined threshold, the data processing system 38 may be configured to estimate the simulated measurements for the second set of parameters.

By leveraging the surrogate models described above, the data processing system 38 may rely less on performing numerous numerical simulations to obtain the same uncertain parameters at the same threshold confidence level as compared to other methodologies. Indeed, as a result, the present embodiments offer a more efficient and objective approach to identify the optimal test design and determine unknown parameter data that may be used to generate or update a geological model.

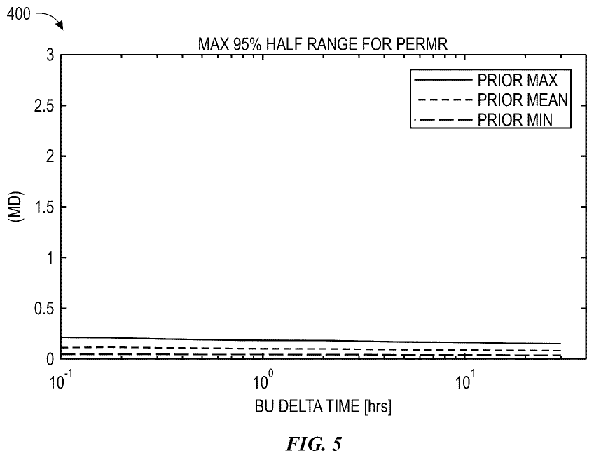

By the way of example, FIGS. 3 to 5 illustrate new test design iterations until the desired test objective is met. FIG. 3 shows the residual uncertainty corresponding to 95% confidence interval for prior maximum, mean, and minimum true value (e.g. actual values in the geological structure) of the parameter for a sample test design (e.g., dual-packer module with 10 bbl/d drawdown flowrate) to characterize the uncertain parameter (e.g., horizontal permeability). As shown in FIG. 3, test design 1 200 does not meet the desired test objective for the uncertain parameter of reaching a residual uncertainty of under 0.5 mD for all cases with a 95% confidence interval. As such, the data processing system 38 generates test design 2 (e.g., additional observation probe) 300, as shown in FIG. 4 using blocks 108-118 of method 100. FIG. 4 shows an improved characterization of the uncertain parameter, but still does not meet the desired test objective for all possible values of the target parameter. Thus, the data processing system 38 generates test design 3 (e.g., dual-packer module with 50 bbl/d drawdown flowrate) 400, as shown in FIG. 5 using blocks 108-118 of method 100. As shown in FIG. 5, test design 3 400 meets the desired test objectives. In some embodiments, the data processing system 38 may generate several test designs comprising different parameters based on the first set of parameters to identify the optimal test design. After identifying the optimal test design, the data processing system 38 continues the method at blocks 120-122 in FIG. 2.

The embodiments described herein provide systems and methods to evaluate the efficacy of different test designs in reducing parameter residual uncertainty for unknown parameters based on various measurement types (e.g. petrophysical logs, core flood experiments etc.). That is, by generating the surrogate model, the present embodiments provide objective simulated measurements that may be used to assess the expected residual uncertainty for the unknown parameters using a simulated test design based on the known parameters and the unknown parameters. The surrogate model may be built on the basis of multiple test design simulations based on different distributions of the uncertainty for the unknown parameters. However, the surrogate model may enable performing a limited number of test design simulations based on being generated by simulated measurement data for the unknown parameters.

Furthermore, the confidence range (e.g. 95% confidence interval) may be used as a statistical measure to evaluate the confidence in the estimation of residual uncertainty in associated stimulated measurements by different test designs. As such, the confidence range and target uncertainty may be used to assess the relative efficacy of the test designs, determine optimal test designs and durations for parameter characterization (e.g. which may include selecting the optimal measurement tool from various petrophysical logs, optimizing the best time to perform a measurement, optimizing the preferred sequence of injection and/or production for sequential data acquisition, etc.). For example, different test designs may comprise different outcome uncertainties, providing quantitative basis for the data processing system 38 to determine whether the current test design meets the test objectives. As a result, the present embodiments enable the data processing system 38 or other suitable computing system to reduce the uncertainty associated with unknown or uncertain parameters in an efficient manner that involves fewer simulations, computing resources (e.g., energy), and computational time to effectively determine properties of a geological region. The efficiency in determining these properties may enable other tools or equipment to modify its operations while performing various operations (e.g., drilling, producing) within the geological region.

The subject matter described in detail above may be defined by one or more clauses, as set forth below.

A system includes a processing system including one or more processors, a memory storing instructions that, when executed by the processing system, are configured to cause the processing system to perform operations including identifying a first set of parameters based on a geological model representative of a subsurface region, identifying a second set of parameters associated with the geological model based on the first set of parameters and one or more field operations previously performed within the subsurface region, wherein the second set of parameters is associated with one or more uncertain parameter, and generating a simulated test design configured to estimate the second set of parameters based on the first set of parameters wherein generating a simulated test design includes determining a sensitivity coefficient matrix at one or more different time points for each of one or more simulated measurements associated with an estimated second set of parameters based on the simulated test design, determining a residual uncertainty associated with the estimated second set of parameters based on the sensitivity coefficient matrix, and generating an updated simulated test design configured to estimate the second set of parameters based on the first set of parameters in response to the residual uncertainty being greater than a threshold.

The system of the preceding clause, wherein the instructions are configured to cause the processing system to generate the updated simulated test design comprises additional operations including updating the model based on one or more additional simulated measurements output by the updated simulated test design, determining an updated sensitivity coefficient matrix at one or more additional different time points for each of the one or more additional simulated measurements, determining an updated residual uncertainty associated with the second set of parameters based on the updated sensitivity coefficient matrix, and generating a test design to implement within the subsurface region based on an updated model in response to the updated residual uncertainty being less than the threshold.

The system of the preceding clause, wherein the instructions are configured to cause the processing system to perform additional operations including generating one or more commands for equipment associated with the subsurface region based on the updated simulated test design in response to the residual uncertainty being less than the threshold, sending the one or more commands to the equipment, wherein the equipment is configured to automatically adjust one or more operations in response to receiving the one or more commands, receiving measurement data from one or more sensors associated with the subsurface region after sending the one or more commands, and generating an updated geological model based on the measurement data.

The system of any preceding clause, wherein the first set of parameters is associated with known parameters based on user input that are static with respect to the simulated test design.

The system of any preceding clause, wherein the second set of parameters is associated with one or more uncertain or unknown parameters that are to be evaluated by the simulated test design.

The system of any preceding clause, wherein the model, comprises a surrogate model built using a Polynomial Chaos Expansion method or a Kriging method or other technique enabling fast sensitivity computation.

The system of any preceding clause, wherein the test design comprises performing one or more test operations in the subsurface region.

A tangible, non-transitory, computer-readable medium includes instructions that, when executed by processing circuitry, are configured to cause the processing circuitry to perform operations including identifying a first set of parameters based on a geological model representative of a subsurface region, identifying a second set of parameters associated with the geological model based on the first set of parameters and one or more field operations previously performed within the subsurface region, wherein the second set of parameters is associated with one or more uncertain parameters, and generating a simulated test design configured to estimate the second set of parameters based on the first set of parameters wherein generating a simulated test design includes determining a sensitivity coefficient matrix at one or more different time points for each of one or more simulated measurements associated with the estimated second set of parameters based on the simulated test design, determining a residual uncertainty associated with the estimated second set of parameters based on the sensitivity coefficient matrix, and generating an updated simulated test design configured to estimate the second set of parameters based on the first set of parameters in response to the residual uncertainty being greater than a threshold.

The tangible, non-transitory, computer-readable medium of the preceding clause, wherein the instructions are configured to cause the processing circuitry to perform operations including updating the model based on one or more additional simulated measurements output by the updated simulated test design, determining an updated sensitivity coefficient matrix at one or more additional different time points for each of the one or more additional simulated measurements, determining an updated residual uncertainty associated with the second set of parameters based on the updated sensitivity coefficient matrix, and generating a test design to implement within the subsurface region based on the updated model in response to the updated residual uncertainty being less than the threshold.

The tangible, non-transitory, computer-readable medium of the preceding clause, wherein the instructions are configured to cause the processing circuitry to perform operations including generating one or more commands for equipment associated with the subsurface region based on the updated simulated test design in response to the residual uncertainty being less than the threshold, sending the one or more commands to the equipment, wherein the equipment is configured to automatically adjust one or more operations in response to receiving the one or more commands, receiving measurement data from one or more sensors associated with the subsurface region after sending the one or more commands, and generating an updated geological model based on the measurement data.

The tangible, non-transitory, computer-readable medium of any preceding clause, wherein the first set of parameters is associated with known parameters based on user input that remain static within the test design.

The tangible, non-transitory, computer-readable medium of any preceding clause, wherein the second set of parameters is associated with one or more uncertain or unknown parameters that remain to be evaluated by the test design.

The tangible, non-transitory, computer-readable medium of any preceding clause, wherein the model, corresponds to a surrogate model built using a Polynomial Chaos Expansion method or a Kriging method or other technique enabling fast sensitivity computation.

The tangible, non-transitory, computer-readable medium of any preceding clause, wherein the test design comprises performing one or more test operations within the subsurface region and measuring a feedback response.

A method includes identifying a first set of parameters based on a geological model representative of a subsurface region, identifying a second set of parameters associated with the geological model based on the first set of parameters and one or more field operations previously performed within the subsurface region, wherein the second set of parameters is associated with one or more uncertain parameters, and generating a simulated test design configured to estimate the second set of parameters based on the first set of parameters wherein generating a simulated test design including determining a sensitivity coefficient matrix at one or more different time points for each of one or more simulated measurements associated with the estimated second set of parameters based on the simulated test design, determining a residual uncertainty associated with the estimated second set of parameters based on the sensitivity coefficient matrix, and generating an updated simulated test design configured to estimate the second set of parameters based on the first set of parameters in response to the residual uncertainty being greater than a threshold.

The method of the preceding clause, wherein the method includes updating the model based on one or more additional simulated measurements output by the updated simulated test design, determining an updated sensitivity coefficient matrix at one or more additional different time points for each of the one or more additional simulated measurements, determining an updated residual uncertainty associated with the second set of parameters based on the updated sensitivity coefficient matrix, and generating a test design to implement within the subsurface region based on the updated model in response to the updated residual uncertainty being less than the threshold.

The method of the preceding clause, wherein the method includes generating one or more commands for equipment associated with the subsurface region based on the updated simulated test design in response to the residual uncertainty being less than the threshold, sending the one or more commands to the equipment, wherein the equipment is configured to automatically adjust one or more operations in response to receiving the one or more command, receiving measurement data from one or more sensors associated with the subsurface region after sending the one or more commands, and generating an updated geological model based on the measurement data.

The method of the preceding clause, wherein the method includes generating one or more additional commands for additional equipment associated with the subsurface region based on the updated geological model and sending the one or more additional commands to the additional equipment, wherein the additional equipment is configured to automatically adjust one or more additional operations in response to receiving the one or more commands.

The method of any preceding clause, wherein the first set of parameters is associated with known parameters based on user input that remain static within the test design.

The method of any preceding clause, wherein the second set of parameters is associated with one or more uncertain or unknown parameters that remain to be evaluated by the test design.

The foregoing description, for purpose of explanation, has been described with reference to specific embodiments. However, the illustrative discussions above are not intended to be exhaustive or to limit the disclosure to the precise forms disclosed. Many modifications and variations are possible in view of the above teachings. Moreover, the order in which the elements of the methods described herein are illustrated and described may be re-arranged, and/or two or more elements may occur simultaneously. The embodiments were chosen and described in order to best explain the principles of the disclosure and its practical applications, to thereby enable others skilled in the art to best utilize the disclosure and various embodiments with various modifications as are suited to the particular use contemplated.

Finally, the techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. A system, comprising:
a processing system comprising one or more processors;
a memory storing instructions, that when executed by the processing system, are configured to cause the processing system to perform operations comprising:
identifying a first set of parameters based on a geological model representative of a subsurface region;
identifying a second set of parameters associated with the geological model based on the first set of parameters and one or more field operations previously performed within the subsurface region, wherein the second set of parameters is associated with one or more uncertain parameters;
generating a simulated test design configured to estimate the second set of parameters based on the first set of parameters wherein generating a simulated test design comprises:
determining a sensitivity coefficient matrix at one or more different time points for each of one or more simulated measurements associated with an estimated second set of parameters based on the simulated test design;
determining a residual uncertainty associated with the estimated second set of parameters based on the sensitivity coefficient matrix; and
generating an updated simulated test design configured to estimate the second set of parameters based on the first set of parameters in response to the residual uncertainty being greater than a threshold.

2. The system of claim 1, wherein the instructions are configured to cause the processing system to perform additional operations comprising:
generating one or more commands for equipment associated with the subsurface region based on the updated simulated test design in response to the residual uncertainty being less than the threshold;
sending the one or more commands to the equipment, wherein the equipment is configured to automatically adjust one or more operations in response to receiving the one or more commands;
receiving measurement data from one or more sensors associated with the subsurface region after sending the one or more commands; and
generating an updated geological model based on the measurement data.

3. The system of claim 1, wherein the first set of parameters is associated with known parameters based on user input that are static with respect to the simulated test design.

4. The system of claim 1, wherein the second set of parameters is associated with one or more uncertain or unknown parameters that are to be evaluated by the simulated test design.

5. The system of claim 1, wherein the model, comprises a surrogate model built using a Polynomial Chaos Expansion method or a Kriging method or other technique enabling fast sensitivity computation.

6. The system of claim 1, wherein the instructions are configured to cause the processing system to generate the updated simulated test design comprises additional operations comprising:
updating the model based on one or more additional simulated measurements output by the updated simulated test design;
determining an updated sensitivity coefficient matrix at one or more additional different time points for each of the one or more additional simulated measurements;
determining an updated residual uncertainty associated with the second set of parameters based on the updated sensitivity coefficient matrix; and
generating a test design to implement within the subsurface region based on an updated model in response to the updated residual uncertainty being less than the threshold.

7. The system of claim 6, wherein the test design comprises performing one or more test operations in the subsurface region.

8. A tangible, non-transitory, computer-readable medium comprising instructions that, when executed by processing circuitry, are configured to cause the processing circuitry to perform operations comprising:
identifying a first set of parameters based on a geological model representative of a subsurface region;
identifying a second set of parameters associated with the geological model based on the first set of parameters and one or more field operations previously performed within the subsurface region, wherein the second set of parameters is associated with one or more uncertain parameters;
generating a simulated test design configured to estimate the second set of parameters based on the first set of parameters wherein generating a simulated test design comprises:
determining a sensitivity coefficient matrix at one or more different time points for each of one or more simulated measurements associated with the estimated second set of parameters based on the simulated test design;
determining a residual uncertainty associated with the estimated second set of parameters based on the sensitivity coefficient matrix; and
generating an updated simulated test design configured to estimate the second set of parameters based on the first set of parameters in response to the residual uncertainty being greater than a threshold.

9. The tangible, non-transitory, computer-readable medium of claim 8, wherein the first set of parameters is associated with known parameters based on user input that remain static within the test design.

10. The tangible, non-transitory, computer-readable medium of claim 8, wherein the second set of parameters is associated with one or more uncertain or unknown parameters that remain to be evaluated by the test design.

11. The tangible, non-transitory, computer-readable medium of claim 8, wherein the instructions are configured to cause the processing circuitry to perform operations comprising:
generating one or more commands for equipment associated with the subsurface region based on the updated simulated test design in response to the residual uncertainty being less than the threshold;
sending the one or more commands to the equipment, wherein the equipment is configured to automatically adjust one or more operations in response to receiving the one or more commands;
receiving measurement data from one or more sensors associated with the subsurface region after sending the one or more commands; and
generating an updated geological model based on the measurement data.

12. The tangible, non-transitory, computer-readable medium of claim 8, wherein the model, corresponds to a surrogate model built using a Polynomial Chaos Expansion method or a Kriging method or other technique enabling fast sensitivity computation.

13. The tangible, non-transitory, computer-readable medium of claim 8, wherein the instructions are configured to cause the processing circuitry to perform operations comprising:
updating the model based on one or more additional simulated measurements output by the updated simulated test design;
determining an updated sensitivity coefficient matrix at one or more additional different time points for each of the one or more additional simulated measurements;
determining an updated residual uncertainty associated with the second set of parameters based on the updated sensitivity coefficient matrix; and
generating a test design to implement within the subsurface region based on the updated model in response to the updated residual uncertainty being less than the threshold.

14. The tangible, non-transitory, computer-readable medium of claim 8, wherein the test design comprises performing one or more test operations within the subsurface region and measuring a feedback response.

15. A method comprising:
identifying a first set of parameters based on a geological model representative of a subsurface region;
identifying a second set of parameters associated with the geological model based on the first set of parameters and one or more field operations previously performed within the subsurface region, wherein the second set of parameters is associated with one or more uncertain parameters;
generating a simulated test design configured to estimate the second set of parameters based on the first set of parameters wherein generating a simulated test design comprises:
determining a sensitivity coefficient matrix at one or more different time points for each of one or more simulated measurements associated with the estimated second set of parameters based on the simulated test design;
determining a residual uncertainty associated with the estimated second set of parameters based on the sensitivity coefficient matrix; and
generating an updated simulated test design configured to estimate the second set of parameters based on the first set of parameters in response to the residual uncertainty being greater than a threshold.

16. The method of claim 15, wherein the first set of parameters is associated with known parameters based on user input that remain static within the test design.

17. The method of claim 15, wherein the second set of parameters is associated with one or more uncertain or unknown parameters that remain to be evaluated by the test design.

18. The method of claim 15, comprising:
generating one or more commands for equipment associated with the subsurface region based on the updated simulated test design in response to the residual uncertainty being less than the threshold;
sending the one or more commands to the equipment, wherein the equipment is configured to automatically adjust one or more operations in response to receiving the one or more commands;
receiving measurement data from one or more sensors associated with the subsurface region after sending the one or more commands; and
generating an updated geological model based on the measurement data.

19. The method of claim 15, comprising:
generating one or more additional commands for additional equipment associated with the subsurface region based on the updated geological model; and
sending the one or more additional commands to the additional equipment, wherein the additional equipment is configured to automatically adjust one or more additional operations in response to receiving the one or more commands.

20. The method of claim 15, comprising:
updating the model based on one or more additional simulated measurements output by the updated simulated test design;
determining an updated sensitivity coefficient matrix at one or more additional different time points for each of the one or more additional simulated measurements;
determining an updated residual uncertainty associated with the second set of parameters based on the updated sensitivity coefficient matrix; and
generating a test design to implement within the subsurface region based on the updated model in response to the updated residual uncertainty being less than the threshold.
